(19) United States
(12) Patent Application Publication
(10) Pub. No.: US 2026/0005090 A1
(43) Pub. Date: Jan. 1, 2026

(54) TEMPERATURE MEASUREMENT DEVICE FOR MEASURING A SURFACE TEMPERATURE OF A SEMICONDUCTOR PACKAGE

(71) Applicant: Sandisk Technologies, Inc., Milpitas, CA (US)

(72) Inventors: Eyal Hamo, Nahariya (IL); Eran Moshe, Rosh Haayin (IL); Apratim Sanyal, Bangalore (IN)

(21) Appl. No.: 18/760,901

(22) Filed: Jul. 1, 2024

(51) Int. Cl. H01L 23/34; H01L 21/66; H01L 23/00; H01L 23/31; H01L 25/065; H10B 80/00

(52) U.S. Cl. CPC H01L 23/34; H01L 22/32; H01L 23/3135; H01L 25/0657; H10B 80/00; H01L 24/13; H01L 24/48; H01L 2224/13023; H01L 2224/48148; H01L 2224/48228; H01L 2225/06506; H01L 2924/1438

(57) ABSTRACT

A semiconductor package includes at least one internal temperature sensor to detect an operating temperature of the semiconductor package. The operating temperature is based on a surface temperature of an enclosure of the semiconductor package. As such, the at least one internal temperature sensor is positioned within a cavity defined by the enclosure to measure the temperature of the enclosure. The at least one internal temperature sensor can be coupled to an inner side of the enclosure or it can be proximate to the enclosure. Temperature measurements provided by the at least one internal temperature sensor are used to determine whether the semiconductor package is operating within operating temperature ranges specified by one or more standards.

### BACKGROUND

Semiconductor packages, such as non-volatile memory devices, are used in various electronic devices such as cellular telephones, digital cameras, personal digital assistants, medical electronics, mobile computing devices, and the like. Because of its inclusion in most modern electronic devices, the demand for packaged memory devices is increasing. Additionally, as processing expectations increase and the size of electronic devices decrease, the desire for higher capacity, smaller size, and higher performance of these memory devices increases with demand. However, as performance capabilities of the memory device increases, so does the amount of heat that is generated by the electronic components of the semiconductor package. The more heat that is generated, the higher the operating temperature of the semiconductor package.

Certain industry specifications require semiconductor packages to operate in a range of temperatures. For example, the Joint Electron Device Engineering Council (JEDEC) standards specify that a semiconductor package must support operating temperatures between negative twenty-five degrees Celsius and eighty-five degrees Celsius. The JEDEC standard also specifies that the operating temperature of the semiconductor package is based on the surface temperature of a case or an enclosure of the semiconductor package.

To determine the surface temperature of the enclosure of the semiconductor package, a third-party external thermocouple is typically attached to the outside of the enclosure. However, during operation, different portions of the enclosure of the semiconductor package have higher or lower temperatures when compared with other portions. In some cases, the difference in temperature is based on the operations that are being performed by the semiconductor package. Therefore, it is difficult to accurately determine whether the semiconductor package is operating within the temperature range specified by the standards.

Accordingly, it would be advantageous for a semiconductor package to have tools that accurately measure the operating temperature of a semiconductor package.

### SUMMARY

The present disclosure describes a semiconductor package having at least one internal temperature sensor to detect an operating temperature of the semiconductor package. In an example, the operating temperature of the semiconductor package is based, at least in part, on a temperature of an enclosure or case of the semiconductor package. As such, the at least one internal temperature sensor is configured and positioned, within a cavity defined by the enclosure, to measure the temperature of the enclosure or case.

For example, the at least one temperature sensor is positioned at a centermost portion of the enclosure. In other examples, multiple temperature sensors are positioned at various locations within the cavity defined by the enclosure. In some examples, the at least one temperature sensor is attached directly to a surface of the enclosure. In yet other examples, the at least one temperature sensor is positioned within a molding compound of the semiconductor package.

In some examples, and depending on the number of temperature sensors within the enclosure, a single temperature measurement is taken. In such an example, the operating temperature of the semiconductor package is based, at least in part, on the single temperature measurement. In other examples, multiple temperature measurements are taken and the operating temperature of the semiconductor package is based, at least in part, on the multiple measurements. In still yet other examples, the frequency of the temperature measurements and/or the number/position of temperature sensors that are read is based, at least in part, on an operating state of the semiconductor package.

Accordingly, examples of the present disclosure describe a semiconductor package that includes a substrate, an integrated circuit electrically coupled to the substrate and a stack of semiconductor dies disposed on the substrate. In an example, the semiconductor package also includes an enclosure that defines a cavity and surrounds the integrated circuit and the stack of semiconductor dies. The semiconductor package also includes a plurality of temperature sensors provided within the cavity. In an example, the plurality of temperature sensors measure a temperature of the enclosure.

Other examples describe a method that includes receiving a request for a temperature measurement of an enclosure of a semiconductor package. Based on receiving the request, an operating state of the semiconductor package is determined. When the operating state of the semiconductor package is determined, a temperature reading of at least one temperature sensor of a plurality of temperature sensors contained within a cavity defined by the enclosure of the semiconductor package is determined. In an example, the at least one temperature sensor of the plurality of temperature sensors that is read is based, at least in part, on the determined operating state. The temperature measurement is then provided to a requesting device.

The present disclosure also describes a semiconductor package that includes a substrate, an integrated circuit electrically coupled to the substrate, and at least one semiconductor die electrically coupled to the substrate. An enclosing means surrounds the integrated circuit and the at least one semiconductor die. The semiconductor package also includes a plurality of temperature measurement means adjacent the enclosing means. In an example, the plurality of temperature measurement means provides a temperature of the enclosing means to the integrated circuit.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1 is a block diagram of a system that includes a host device and a data storage device according to an example

FIG. 2 is a cross-sectional view of a semiconductor package having a number of internal temperature sensors for measuring a surface temperature of an enclosure according to first example.

FIG. 3 is a cross-sectional view of a semiconductor package having a number of internal temperature sensors for measuring a surface temperature of an enclosure according to a second example.

FIG. 4 is a cross-sectional view of a semiconductor package having a number of internal temperature sensors for measuring a surface temperature of an enclosure according to a third example.

FIG. 5 is a cross-sectional view of a semiconductor package having a number of internal temperature sensors for measuring a surface temperature of an enclosure according to a fourth example.

FIG. 6 illustrates a method for measuring a surface temperature of an enclosure of a semiconductor package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

As previously explained, as the demand for semiconductor packages increases, so does the demand for higher capacity, smaller size, and higher performance. However, as performance capabilities of a semiconductor package increases, the amount of heat that it is generated during operation also increases-which raises the operating temperature of the semiconductor package.

As also previously explained, certain industry specifications require semiconductor packages to operate in a predefined range of temperatures. For example, the Joint Electron Device Engineering Council (JEDEC) standards specify that a semiconductor package must support operating temperatures between negative twenty-five degrees Celsius and eighty-five degrees Celsius. The JEDEC standard also specifies that the operating temperature of the semiconductor package is based on the surface temperature of the case or the enclosure of the semiconductor package (referred to in the JEDEC standard as Tcase).

In current semiconductor packages, there is no way to directly measure the surface temperature of the enclosure of the semiconductor package. While current semiconductor packages have an internal temperature sensor, this particular internal temperature sensor is used for measuring a temperature of one or more semiconductor dies in the semiconductor package.

Therefore, in order to obtain or determine the surface temperature of the enclosure, a third-party external thermocouple is typically attached to the outside of the enclosure of the semiconductor package. However, this option is not always available. For example, if the semiconductor package is included as part of an electronic device (e.g., a mobile phone), there may not be enough room within the housing the electronic device for the thermocouple.

In other examples, the temperature of the one or more semiconductor dies varies depending on an operating state of the of the semiconductor package. For example, if the semiconductor package is a memory device, the temperature of the one or more semiconductor dies varies based on whether a write operation or a read operation is being performed. In another example, the temperature of the one or more semiconductor dies varies based on an amount of data that is stored on the semiconductor dies.

The varying temperature of the one or more semiconductor dies can also impact the surface temperature of the enclosure. For example, different portions of the enclosure of the semiconductor package may have higher or lower temperatures when compared with other portions based, at least in part, on the differing temperatures of the semiconductor dies. As such, it is difficult to accurately measure and/or determine the surface temperature of the enclosure of the semiconductor package to determine whether the semiconductor package is operating within the temperature ranges required by various standards.

To address the above, the present disclosure describes a semiconductor package that includes one or more temperature sensors arranged and configured to accurately determine an operating temperature of the semiconductor package. For example, the one or more temperature sensors are placed within a cavity defined by an enclosure of the semiconductor package. In some examples, the one or more temperature sensors are placed or located on an inner surface of the enclosure. In other examples, the one or more temperature sensors are placed adjacent the enclosure.

Regardless of the number and/or position of the temperature sensors within the cavity, the temperature sensors are used to measure a current temperature of the enclosure of the semiconductor package. In addition, temperature measurements from one or more of the sensors may be read and/or determined based, at least in part, on an operating state of the semiconductor package. For example a first set or subset of temperature sensors are used to measure the surface temperature of the enclosure when a first type of operation is executed on the semiconductor package and a second set or subset of temperature sensors are used to measure the surface temperature of the enclosure when a second type of operation is executed on the semiconductor package.

In examples in which the semiconductor package is a memory device, such as, for example, a universal flash storage (UFS) device, a first set or subset of temperature sensors are used to measure the surface temperature of the enclosure when a first amount of data is stored by the semiconductor package and a second set or subset of temperature sensors are used to measure the surface temperature of the enclosure when a second amount of data is stored by the semiconductor package.

In an example, the temperature measurements are provided to an integrated circuit of the semiconductor package. The integrated circuit uses the information to determine whether the semiconductor package is operating in approved operating temperature ranges (e.g., a temperature range outlined in one or more standards specifications). In another example, the integrated circuit uses the information to perform various thermal management procedures or operations. In yet another example, the integrated circuit uses the information to determine whether the temporarily reduce a performance of the semiconductor package in order to bring the operating temperature of the semiconductor package back to acceptable levels.

Accordingly, many technical benefits may be realized including, but not limited to, ensuring the semiconductor package is operating within temperature ranges specified by industry standards, simplifying the determination of the operating temperature of the semiconductor package without the need for additional equipment (e.g., thermocouples), and accurately determining an operating temperature of the semiconductor package based on operating conditions and/or states of the semiconductor package. In some examples, all of this is done without increasing the size and/or height of the semiconductor package.

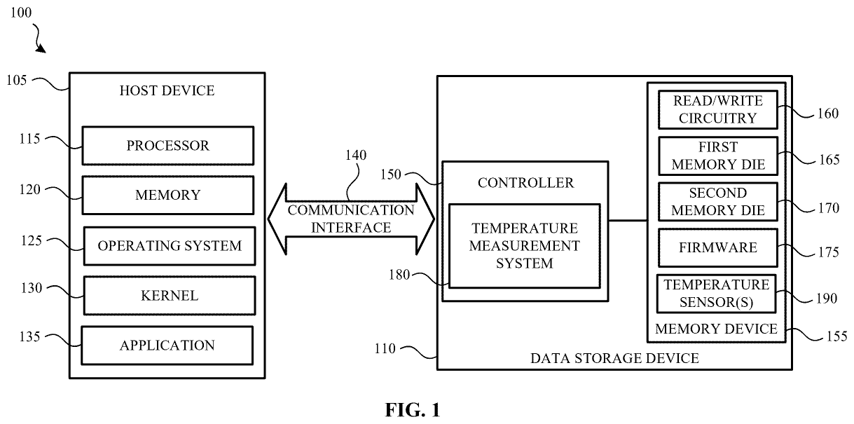

These and other examples will be described in more detail with respect to FIG. 1-FIG. 6.

FIG. 1 is a block diagram of a system 100 that includes a host device 105 and a data storage device 110 according to an example. In an example, the host device 105 includes a processor 115 and a memory 120 (e.g., main memory). The memory 120 includes or is otherwise associated with an operating system 125, a kernel 130 and/or an application 135.

The processor 115 can execute various instructions, such as, for example, instructions from the operating system 125 and/or the application 135. The processor 115 may include circuitry such as a microcontroller, a Digital Signal Processor (DSP), an Application-Specific Integrated Circuit (ASIC), a Field Programmable Gate Array (FPGA), hard-wired logic, analog circuitry and/or various combinations thereof. In an example, the processor 115 includes a System on a Chip (SoC).

In an example, the memory 120 can be used by the host device 105 to store data used, or otherwise executed by, the processor 115. Data stored in the memory 120 may include instructions provided by the data storage device 110 via a communication interface 140. The data stored in the memory 120 may also include data used to execute instructions from the operating system 125 and/or one or more applications 135. The memory 120 may be a single memory or may include multiple memories, such as, for example one or more non-volatile memories, one or more volatile memories, or a combination thereof.

In an example, the operating system 125 creates a virtual address space for the application 135 and/or other processes executed by the processor 115. The virtual address space maps to locations in the memory 120. The operating system 125 may also include or otherwise be associated with a kernel 130. The kernel 130 may include instructions for managing various resources of the host device 105 (e.g., memory allocation), handling read and write requests and so on.

The communication interface 140 communicatively couples the host device 105 and the data storage device 110. The communication interface 140 may be a Serial Advanced Technology Attachment (SATA), a PCI express (PCIe) bus, a Small Computer System Interface (SCSI), a Serial Attached SCSI (SAS), Ethernet, Fibre Channel, or Wi-Fi. As such, the host device 105 and the data storage device 110 need not be physically co-located and may communicate over a network such as a Local Area Network (LAN) or a Wide Area Network (WAN), such as the internet. In addition, the host device 105 may interface with the data storage device 110 using a logical interface specification such as Non-Volatile Memory express (NVMe) or Advanced Host Controller Interface (AHCI).

In some examples, the data storage device 110 is attached to, or embedded within, the host device 105. In another example, the data storage device 110 is a component (e.g., a solid state drive (SSD)) of a network accessible data storage system, a solid state memory, a network-attached storage system, a cloud data storage system, and the like. In yet other examples, the data storage device 110 is implemented as an external device or a portable device that can be communicatively or selectively coupled to the host device 105. For example, the data storage device 110 is a USB drive or a USB data storage device and is communicatively coupled to the host device 105 using one or more host interfaces (e.g., a USB interface).

The data storage device 110 includes a controller 150 and a memory device 155. In an example, the memory device 155 may also be referred to herein as a semiconductor package having one or more semiconductor dies. The controller 150 is communicatively coupled to the memory device 155. In another example, the controller 150 is part of the memory device 155.

In an example, the memory device 155 includes one or more memory dies (e.g., a first memory die 165 and a second memory die 170) or other semiconductor dies. Although two memory dies are shown, the memory device 155 may include any number of memory dies (e.g., one memory die, two memory dies, eight memory dies, or another number of memory dies). Additionally, although memory dies are specifically mentioned, the memory device 155 may include any non-volatile memory device, storage device, storage elements or storage medium including NAND flash memory cells and/or NOR flash memory cells.

The memory cells can be one-time programmable, few-time programmable, or many-time programmable. Additionally, the memory cells may be single-level cells (SLCs), multi-level cells (MLCs), triple-level cells (TLCs), quad-level cells (QLCs), penta-level cells (PLCs), and/or use any other memory technologies. The memory cells may be arranged in a two-dimensional configuration or a three-dimensional configuration.

The memory device 155 also includes support circuitry. In an example, the support circuitry includes read/write circuitry 160. The read/write circuitry 160 supports the operation of the memory dies of the memory device 155. Although the read/write circuitry 160 is depicted as a single component, the read/write circuitry 160 may be divided into separate components, such as, for example, read circuitry and write circuitry. The read/write circuitry 160 may be external to the memory dies of the memory device 155. In another example, one or more of the memory dies may include corresponding read/write circuitry 160 that is operable to read data from and/or write data to storage elements within one individual memory die independent of other read and/or write operations on any of the other memory dies.

The memory device 155 also includes one or more temperatures sensors 190. The temperature sensors 190 are used to determine a surface temperature of a housing, case or enclosure associated with the memory device 155. For example, one or more temperature sensors 190 may be positioned at single location within the enclosure or at multiple locations within the enclosure. In an example, the one or more temperature sensors 190 are directly attached to an inner surface of the enclosure. In another example, the one or more temperature sensors are at least partially embedded within the enclosure. In yet another example, the one or more temperature sensors 190 are proximate the enclosure. For example, the one or more temperature sensors 190 are contained in a molding compound and positioned between an inner surface of the enclosure and the memory dies.

As previously described, the data storage device 110 includes a controller 150. The controller 150 is communicatively coupled to the memory device 155 via a bus, an interface or other communication circuitry. In an example, the communication circuitry includes one or more channels that enable the controller 150 to communicate with the first memory die 165 and/or the second memory die 170 of the memory device 155. In another example, the communication circuitry includes multiple distinct channels which enables the controller 150 to communicate with the first memory die 165 independently and/or in parallel with the second memory die 170.

The controller 150 includes circuitry for executing instructions. For example, the controller 150 includes one or more processors, one or more microcontrollers, one or more DSPs, one or more ASICs, one or more FPGAs, hard-wired logic, analog circuitry and/or a combination thereof. In another example, the controller 150 includes a SoC or multiple SoCs. Although a single controller 150 is shown and described, the data storage device 110 can include multiple controllers 150. In such examples, each controller 150 is responsible for particular operations (or a subset of operations) described herein.

In an example, the controller 150 receives instructions and/or data from the host device 105. In another example, the instructions originate from firmware 175 associated with the data storage device 110 and/or the memory device 155. In yet another example, the controller 150 sends data to the host device 105 via the communication interface 140. The controller 150 also sends data and/or commands to and/or receive data from the memory device 155.

For example, the controller 150 may send data and a corresponding write command to the memory device 155 to cause the memory device 155 to store data at a specified address of the memory device 155. In an example, the write command specifies a physical address of a portion of the memory device 155. The controller 150 may also send one or more read commands to the memory device 155. In an example, the read command specifies the physical address of a portion of the memory device 155 at which the data is stored.

The controller 150 also receives temperature measurements from the one or more temperature sensors 190 associated with the memory device 155. In an example, the controller 150 continuously receives temperature measurements from the one or more temperature sensors 190. In another example, the controller 150 periodically receives temperature measurements from the one or more temperature sensors 190. In yet another example, the controller 150 receives temperatures measurements from the one or more temperature sensors 190 based, at least in part, on a command received from the host device 105 and/or a type of command that is being executed on the memory device 155.

In an example, the controller 150 includes, or is otherwise associated with, a temperature measurement system 180. In an example, the temperature measurement system 180 is packaged functional hardware units designed for use with other components/systems, a portion of a program code (e.g., software or firmware) executable by a processor or processing circuitry, or a self-contained hardware and/or software component that interfaces with other components and/or systems.

The temperature measurement system 180 is operable to determine whether and when to request temperature measurements from the one or more temperature sensors 190. In examples in which the memory device 155 includes multiple temperature sensors 190, the temperature measurement system 180 is also operable to determine which temperature measurements from which temperature sensors 190 should be used.

For example, the temperature measurement system 180 is also operable to determine an operating state of the data storage device 110 and/or the memory device 155. Based, at least in part, on the determined operating state, the temperature measurement system 180 identifies or selects which temperature measurements of which temperature sensors 190 will be used in determining the surface temperature of the enclosure.

For example, the temperature measurement system 180 can activate certain temperature sensors 190 based on the determined operating state of the memory device 155. In another example, the temperature measurement system 180 receives temperature measurements from each temperature sensor 190 but only uses temperature measurements from certain, selected temperature sensors 190. The temperature measurement system 180 can also determine a frequency at which the temperature measurements are taken and/or received based, at least in part, on the operating state of the data storage device 110 and/or the memory device 155.

In some examples, the operating state of the data storage device 110 and/or the memory device 155 is based, at least in part, on a type of command that is received from the host device 105 and/or executed on the data storage device 110 and/or the memory device 155. In another example, the operating state of the data storage device 110 and/or the memory device 155 is based, at least in part, on an amount of data stored in the memory device 155 (e.g., which memory dies are written to and/or read from). In yet another example, the operating state of the data storage device 110 and/or the memory device 155 is based on a number of program/erase (P/E) cycles, an age of the data storage device 110 and/or the memory device, the type of application (e.g., automotive, electronic device) for which the data storage device 110 is being used and so on.

Although specific examples have been given, these are for illustrative purposes only. It is contemplated that other factors can be considered and used to determine a frequency at which temperature measurements are received and from which temperature sensors 190 the temperature measurements are received.

When the temperature measurements are received, the temperature measurement system 180 determines the surface temperature of the enclosure and/or determines the operating temperature of the memory device 155 and/or the data storage device 110. This information can then be used by the controller 150 and/or the temperature measurement system 180 to implement various thermal management procedures. The information can also be provided to the host device 105.

In an example, the temperature measurement system 180 considers or accounts for a location of the one or more temperature sensors 190 when determining the surface temperature of the enclosure (referred to as a location tolerance). For example, if the one or more temperature sensors 190 are provided in the molding compound, the temperature measurement system 180 may determine that the actual surface temperature of the enclosure is plus or minus one degree (or more). However, if the one or more temperature sensors 190 are provided on the surface of the enclosure, the temperature measurement system 180 does not consider any location tolerance when determining the surface temperature of the enclosure.

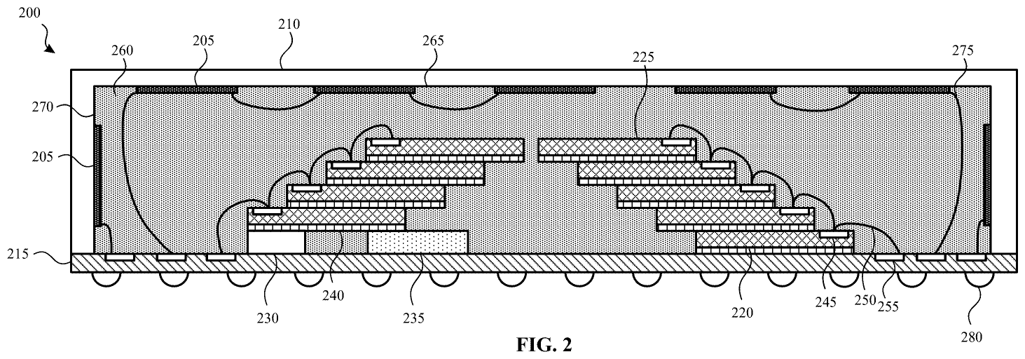

FIG. 2 is a cross-sectional view of a semiconductor package 200 having a number of internal temperature sensors 205 for measuring a surface temperature of an enclosure 210 according to an example. In an example, the semiconductor package 200 is similar to the memory device 155 shown and described with respect to FIG. 1.

In an example, the semiconductor package 200 includes a substrate 215. The substrate 215 forms a base layer for the semiconductor package 200. The substrate 215 is formed as a semiconducting material and/or is formed from any suitable material or material composition that includes semiconducting properties/characteristics.

The semiconductor package 200 also includes a plurality of semiconductor dies 220. In an example, the semiconductor dies 220 are NAND memory dies. However, it is understood that the plurality of semiconductor dies 220 can be formed as any volatile or non-volatile memory die, or any other suitable circuit stack-up configuration.

As shown in FIG. 2, the plurality of semiconductor dies 220 are disposed over, positioned on, and/or formed above substrate 215. In a non-limiting example, the plurality of semiconductor dies 220 are staggered or stepped with respect to one another when disposed over the substrate 215. As such, at least a portion of a top surface 225 of each semiconductor die 220 of the plurality of semiconductor dies 220 is uncovered by the adjacent die positioned thereon.

In an example, the semiconductor dies 220 of the semiconductor package 200 are arranged in one or more stacks. For example, as shown in FIG. 2, the semiconductor package 200 includes two stacks of semiconductor dies 220 that are positioned adjacent each other on the substrate 215. In this example, one of the stacks includes four semiconductor dies 220 and another stack includes five semiconductor dies 220. However, it is understood that the number of semiconductor dies 220 included in each stack is illustrative and a stack can include any number of semiconductor dies 220.

In the example shown in FIG. 2, the stack with four semiconductor dies 220 is placed on or otherwise stacked on top of a spacer 230 and an integrated circuit 235 (e.g., a controller) while the stack with five semiconductor dies 220 is placed directly on a top surface of the substrate 215.

In an example a die attach film (DAF) 240 is disposed or otherwise provided on a bottom surface of each semiconductor die 220. For example, the DAF 240 is disposed between each of the plurality of semiconductor dies 220, between the semiconductor die 220 and the substrate 215 and/or between the semiconductor die 220 and the integrated circuit 235 and the spacer 230.

For example, the DAF 240 is disposed over and/or substantially covers a bottom surface of each semiconductor die 220 (e.g., opposite a top surface) to bond or connect the semiconductor dies 220 to adjacent semiconductor dies 220, the substrate 215, the spacer 230 and/or the integrated circuit 235. The DAF 240 is formed as any suitable adhesive material capable of withstanding the operational parameters, characteristics, and/or constraints (e.g., temperature change) of the semiconductor package 200.

Each of the plurality of semiconductor dies 220 includes at least one die pad, connection pad, or die contact 245. As shown in FIG. 2, each semiconductor die 220 includes a die contact 245 formed in/on the semiconductor die 220 and/or on the uncovered (portion) of the semiconductor die 220.

In an example, the die contacts 245 are used to electrically couple each of the semiconductor dies 220 to one another, and/or to electrically couple the semiconductor dies 220 to the substrate 215. For example, a bond wire 250 electrically and/or communicatively couples a die contact 245 to a substrate contact 255 formed directly in and/or directly on the substrate 215.

Die contacts 245 are formed in the plurality of semiconductor dies 220 are of a predetermined configuration and/or circuitry based on operational and/or structural parameters of the semiconductor package 200. It is understood that the number of die contacts 245 and/or the configuration of die contacts 245 of the semiconductor package 200 shown in FIG. 2 is illustrative. As such, other non-limiting examples of the semiconductor package 200 can include more or fewer die contacts 245 and/or can include distinct configurations or circuitry than the non-limiting example shown in FIG. 2.

As previously discussed, the semiconductor package 200 also includes an enclosure 210. The enclosure 210 defines a cavity that houses the various electronic components described herein. The enclosure 210 may be made from any suitable material.

The semiconductor package 200 also includes a molding compound 260. The molding compound 260 is disposed within the cavity defined by the enclosure 210 and over various portions and/or electronic components of the semiconductor package 200. For example, the molding compound 260 is disposed over exposed portions of substrate 215, substrate contacts 255, and at least a portion of the stacked semiconductor dies 220.

As previously described, particular standards (e.g., the JEDEC standard) requires that the semiconductor package 200 operate within a predetermined operating temperature range (e.g., between negative twenty-five degrees Celsius and eighty-five degrees Celsius). In another example, other standards (e.g., one or more automotive standards) specify that the semiconductor package 200 operate at a max performance level within a first operating temperature range (e.g., between negative twenty-five degrees Celsius and eighty-five degrees Celsius) and operate at a reduced performance level when the semiconductor package 200 is outside of that range.

In an example, the operating temperature of the semiconductor package 200 is based on a surface temperature of the enclosure 210. The JEDEC standard refers to this variable as Tcase. Although the JEDEC standard is specifically mentioned, this is for example purposes only.

To determine the surface temperature of the enclosure 210, the semiconductor package 200 also includes one or more temperature sensors 205. As shown in FIG. 2, the temperature sensors 205 are provided within the cavity defined by the enclosure 210 and are directly coupled or attached to an inner surface 265 of the enclosure 210. However, in some examples, the height and/or width of the semiconductor package 200 remains unchanged (e.g., inclusion of the temperature sensors does not require an increase in the height or width of comparable semiconductor packages that do not include temperature sensors 205).

In an example, the semiconductor package 200 may include a single temperature sensor 205 (e.g., disposed in a centermost portion of the enclosure 210). In other examples, such as shown in FIG. 2, the semiconductor package 200 includes multiple temperature sensors 205. In an example, at least one temperature sensor 205 is provided on an inner side of a top surface of the enclosure 210 and at least one other temperature sensor 205 is provided on the inner surface 265 of a sidewall 270 of the enclosure 210.

In an example, the temperature sensors 205 are electrically coupled to the substrate 215 using one or more wires 275 (e.g., bond wires). For example, each temperature sensor 205 is electrically and/or communicatively coupled to the substrate 215 using the wire 275 and a respective substrate contact 255. In an example, one or more traces or other communication paths/channels on or within the substrate 215 electrically and/or communicatively couple one or more of the temperature sensors 205 to the integrated circuit 235.

In another example, one or more traces or other communication paths/channels on or within the substrate 215 electrically and/or communicatively couple one or more of the temperature sensors 205 to respective solder balls 280 on a bottom surface of the substrate 215. The solder balls 280 are used to electrically and/or communicatively couple the semiconductor package 200 to a printed circuit board (PCB) or other device.

In an example, each temperature sensor 205 is electrically coupled to its own respective substrate contact 255. In another example, such as shown in FIG. 2, a first temperature sensor 205 is electrically coupled to a substrate contact 255 and a wire (e.g., a bond wire) daisy chains a second temperature sensor 205 to the first temperature sensor 205.

Regardless of how the temperature sensors 205 are electrically and/or communicatively coupled to the substrate 215, the temperature sensors 205 provide surface temperature readings of the enclosure 210 to the integrated circuit 235. In an example, the integrated circuit 235 knows the position and/or identification of each temperature sensor 205. As such, the integrated circuit 235 can selectively activate and/or receive temperature measurements from desired temperature sensors 205. As previously described, the integrated circuit 235 selectively activates and/or receives temperature measurements from one or more temperature sensors based, at least in part, on a determined operating state of the semiconductor package 200.

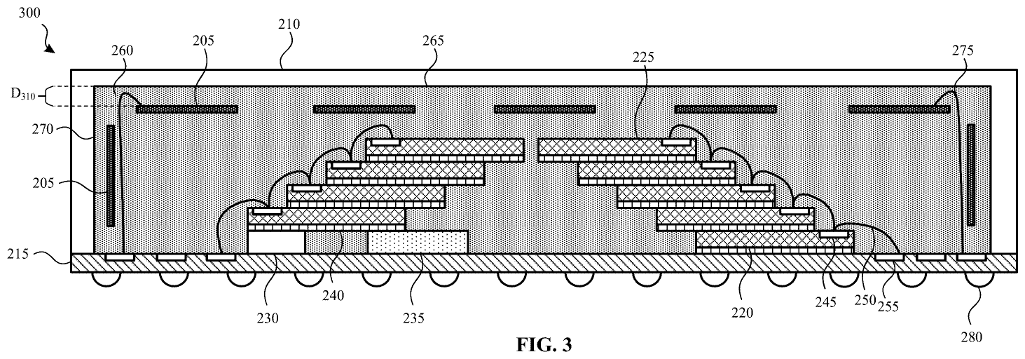

FIG. 3 is a cross-sectional view of a semiconductor package 300 having a number of internal temperature sensors 205 for measuring a surface temperature of an enclosure 210 according to a second example. In an example, the semiconductor package 300 is similar to the semiconductor package 200 shown and described with respect to FIG. 2. As such, and for purposes of clarity and brevity, the various components maintain similar reference numbers and function in the manner previously described.

In the example shown in FIG. 3, the temperature sensors 205 are positioned within the cavity defined by the enclosure 210. However, instead of being directly attached to the inner surface 265 of the enclosure 210, the temperature sensors 205 are positioned proximate the enclosure 210. For example, a distance D 310 at which the temperature sensors 205 are spaced away or apart from the inner surface 265 of the enclosure 210 is based, at least in part, on a clearance distance between the inner surface 265 of the enclosure 210 and the wire 275 that electrically and/or communicatively couples the temperature sensor 205 to the substrate 215.

In an example, because the temperature sensors 205 are not directly contacting the enclosure 210, the integrated circuit 235 may account for the location tolerance by adding or subtracting one degree (or more) from a received temperature reading.

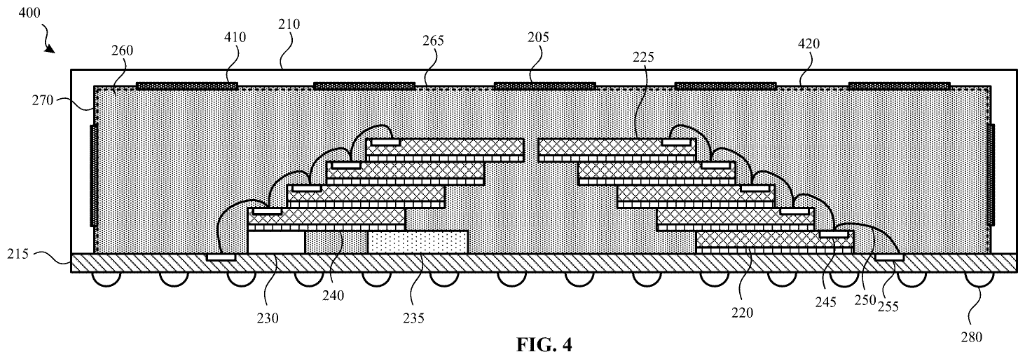

FIG. 4 is a cross-sectional view of a semiconductor package 400 having a number of internal temperature sensors 205 for measuring a surface temperature of an enclosure 210 according to a third example. In an example, the semiconductor package 400 is similar to the semiconductor package 200 shown and described with respect to FIG. 2. As such, and for purposes of clarity and brevity, the various components maintain similar reference numbers and function in the manner previously described.

In this example, the one or more temperature sensors 205 are at least partially embedded in the enclosure 210. For example, the enclosure 210 defines one or more recesses 410 that at least partially contain the temperature sensors 205. In this example, various wires 420 are used to electrically couple the temperature sensors 205 to each other and/or to the substrate 215.

For example, the wires 420 may be integrated with and/or on the enclosure 210. In an example, the wires 420 are copper traces formed in and/or formed on (e.g., printed on) the enclosure 210. In another example, the wires 210 are bond wires.

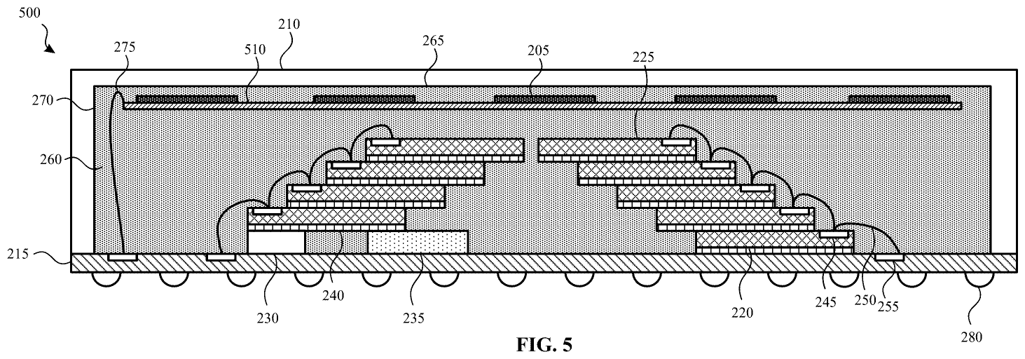

FIG. 5 is a cross-sectional view of a semiconductor package 500 having a number of internal temperature sensors 205 for measuring a surface temperature of an enclosure 210 according to a fourth example. In an example, the semiconductor package 500 is similar to the semiconductor package 200 shown and described with respect to FIG. 2. As such, and for purposes of clarity and brevity, the various components maintain similar reference numbers and function in the manner previously described.

In this example, the temperature sensors 205 are electrically and/or communicatively coupled and/or attached to a wafer 510 or other suitable material. The wafer 510 is also electrically coupled to the substrate 215 using a wire 275. In the example shown, the wafer 510 and the temperature sensors 205 are proximate to the enclosure 210. However, it is contemplated that a top side of the temperature sensors 205 are directly coupled to the inner surface 265 of the enclosure 210 while a bottom side of the temperature sensors 205 are coupled to the wafer 510.

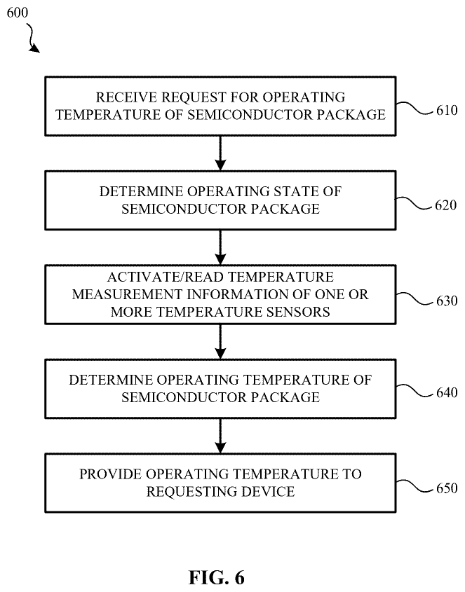

FIG. 6 illustrates a method 600 for measuring a surface temperature of an enclosure of a semiconductor package according to an example. In an example, the method 600 is used to determine an operating temperature of the semiconductor package (e.g., the semiconductor package 200 (FIG. 2)) in accordance with one or more standards. Additionally, in an example, the method 600 is performed by an integrated circuit and/or a controller of the semiconductor package. In yet another example, the method 600 is performed by a host device or other computing device to which the semiconductor package is attached.

Method 600 begins when a request for an operating temperature of the semiconductor package is received (610). In an example, the request is provided from a computing device to which the semiconductor package is coupled and is received by the integrated circuit. In another example, a controller or an integrated circuit of the semiconductor package continuously monitors or checks the operating temperature of the semiconductor package.

When the request is received, the integrated circuit determines (620) an operating state of the semiconductor package. In an example, the operating state includes, but is not limited to, the type of commands currently being executed by/on the semiconductor package, a type of application for which the semiconductor package is being used, an amount of data stored by the semiconductor package, an age of the semiconductor package and so on.

When the operating state of the semiconductor package has been determined, the integrated circuit activates one or more temperature sensors and/or reads/receives temperature measurement information from the one or more temperature sensors. In an example, the one or more temperature sensors are directly coupled to an inner surface of the enclosure of the semiconductor package. In another example, the one or more temperature sensors are proximate the inner surface of the enclosure.

In an example, the integrated circuit selectively activates one or more of the temperature sensors depending on an operating state of the semiconductor package. In another example, a frequency of taking and/or receiving temperature measurement information depends on the operating state of the semiconductor package.

In yet another example, a frequency of taking and/or receiving temperature measurement information from the one or more sensors is based, at least in part, on a previously received and/or determined operating temperature of the semiconductor package. For example, if the determined operating temperature of the semiconductor package is above or below a specified or predetermined operating range, the integrated circuit may take or receive temperature measurements more (or less) frequently when compared to when the operating temperature is within the predetermined operating range.

In yet another example, a frequency of taking and/or receiving temperature measurement is based on whether the operating temperature of the semiconductor package is increasing or decreasing. For example, if the operating temperature of the semiconductor package is increasing, the frequency of temperature measurements also increases. However, if the operating temperature of the semiconductor package is decreasing, the frequency also decreases.

When the temperature measurement information is received, the integrated circuit uses the information to determine (640) an operating temperature of the semiconductor package. In an example, this also includes accounting for a location tolerance of one or more of the temperature sensors. When the operating temperature of the semiconductor package is determined, the operating temperature is provided (650) to the requesting device.

In accordance with the above, examples of the present disclosure describe a semiconductor package, comprising: a substrate; an integrated circuit electrically coupled to the substrate; a stack of semiconductor dies disposed on the substrate; an enclosure defining a cavity that surrounds the integrated circuit and the stack of semiconductor dies; and a plurality of temperature sensors provided within the cavity, the plurality of temperature sensors measuring a surface temperature of the enclosure. In an example, the integrated circuit selectively reads temperature measurements from at least one temperature sensor of the plurality of temperature sensors. In an example, the integrated circuit selectively reads the temperature measurements from the at least one temperature sensor of the plurality of temperature sensors based, at least in part, on a determined operating state of the semiconductor package. In an example, a first set of the plurality of temperature sensors are adjacent a first portion of the enclosure and a second set of the plurality of temperature sensors are adjacent a second portion of the enclosure. In an example, at least one temperature sensor of the plurality of temperature sensors is attached to an inner surface of the enclosure. In an example, at least one temperature sensor of the plurality of temperatures sensors is disposed in a molding compound between a top surface of the stack of semiconductor dies and a top portion of the enclosure. In an example, the plurality of temperature sensors are arranged on a single wafer within the enclosure. In an example, the semiconductor dies of the stack of semiconductor dies comprise memory dies, and at least one of the plurality of temperature sensors is electrically coupled to the substrate.

Examples also describe a method, comprising: receiving a request for a temperature measurement of an enclosure of a semiconductor package; determining an operating state of the semiconductor package; determining a temperature reading of at least one temperature sensor of a plurality of temperature sensors contained in a cavity defined by the enclosure of the semiconductor package, wherein the at least one temperature sensor is selected based, at least in part, on the operating state of the semiconductor package; and providing the temperature measurement to a requesting device. In an example, a first set of the plurality of temperature sensors are adjacent a first portion of the enclosure and a second set of the plurality of temperature sensors are adjacent a second portion of the enclosure. In an example, at least one temperature sensor of the plurality of temperature sensors is attached to an inner surface of the enclosure. In an example, at least one temperature sensor of the plurality of temperatures sensors is disposed in a molding compound between a top surface of a stack of semiconductor dies in the semiconductor package and a bottom surface of the enclosure. In an example, the semiconductor package comprises a solid state memory and the temperature measurement is identified as a Tcase measurement. In an example, the plurality of temperature sensors are arranged on a single wafer within the enclosure.

Examples of the present disclosure also describe a semiconductor package, comprising: a substrate; an integrated circuit electrically coupled to the substrate; at least one semiconductor die electrically coupled to the substrate; an enclosing means surrounding the integrated circuit and the at least one semiconductor die; a plurality of temperature measurement means adjacent the enclosing means, the plurality of temperature measurement means providing a temperature of the enclosing means to the integrated circuit. In an example, the integrated circuit selectively requests the temperature measurements from at least one temperature measurement means of the plurality of temperature measurement means, based at least in part, on a determined operating state of the semiconductor package. In an example, a first temperature measurement means of the plurality of temperature measurement means is adjacent a top portion of the enclosing means and a second temperature measurement means of the plurality of temperature measurement means is adjacent a side portion of the enclosing means. In an example, at least one temperature measurement means of the plurality of temperature measurement means is attached to an inner surface of the enclosing means. In an example, at least one temperature measurement means of the plurality of temperature measurement means is disposed in a molding compound between a top surface of the at least one semiconductor die and a top portion of the enclosing means. In an example, the plurality of temperature measurement means are arranged on a single wafer within the enclosing means.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a substrate;
an integrated circuit electrically coupled to the substrate;
a stack of semiconductor dies disposed on the substrate;
an enclosure defining a cavity that surrounds the integrated circuit and the stack of semiconductor dies; and
a plurality of temperature sensors provided within the cavity, the plurality of temperature sensors measuring a surface temperature of the enclosure.

2. The semiconductor package of claim 1, wherein the integrated circuit selectively reads temperature measurements from at least one temperature sensor of the plurality of temperature sensors.

3. The semiconductor package of claim 2, wherein the integrated circuit selectively reads the temperature measurements from the at least one temperature sensor of the plurality of temperature sensors based, at least in part, on a determined operating state of the semiconductor package.

4. The semiconductor package of claim 1, wherein a first set of the plurality of temperature sensors are adjacent a first portion of the enclosure and a second set of the plurality of temperature sensors are adjacent a second portion of the enclosure.

5. The semiconductor package of claim 1, wherein at least one temperature sensor of the plurality of temperature sensors is attached to an inner surface of the enclosure.

6. The semiconductor package of claim 1, wherein at least one temperature sensor of the plurality of temperatures sensors is disposed in a molding compound between a top surface of the stack of semiconductor dies and a top portion of the enclosure.

7. The semiconductor package of claim 1, wherein the plurality of temperature sensors are arranged on a single wafer within the enclosure.

8. The semiconductor package of claim 1, wherein the semiconductor dies of the stack of semiconductor dies comprise memory dies, and at least one of the plurality of temperature sensors is electrically coupled to the substrate.

9. A method, comprising:
receiving a request for a temperature measurement of an enclosure of a semiconductor package;
determining an operating state of the semiconductor package;
determining a temperature reading of at least one temperature sensor of a plurality of temperature sensors contained in a cavity defined by the enclosure of the semiconductor package, wherein the at least one temperature sensor is selected based, at least in part, on the operating state of the semiconductor package; and
providing the temperature measurement to a requesting device.

10. The method of claim 9, wherein a first set of the plurality of temperature sensors are adjacent a first portion of the enclosure and a second set of the plurality of temperature sensors are adjacent a second portion of the enclosure.

11. The method of claim 9, wherein at least one temperature sensor of the plurality of temperature sensors is attached to an inner surface of the enclosure.

12. The method of claim 9, wherein at least one temperature sensor of the plurality of temperatures sensors is disposed in a molding compound between a top surface of a stack of semiconductor dies in the semiconductor package and a bottom surface of the enclosure.

13. The method of claim 9, wherein the semiconductor package comprises a solid state memory and the temperature measurement is identified as a Tcase measurement.

14. The method of claim 9, wherein the plurality of temperature sensors are arranged on a single wafer within the enclosure.

15. A semiconductor package, comprising:
a substrate;
an integrated circuit electrically coupled to the substrate;
at least one semiconductor die electrically coupled to the substrate;
an enclosing means surrounding the integrated circuit and the at least one semiconductor die;
a plurality of temperature measurement means adjacent the enclosing means, the plurality of temperature measurement means providing a temperature of the enclosing means to the integrated circuit.

16. The semiconductor package of claim 15, wherein the integrated circuit selectively requests the temperature measurements from at least one temperature measurement means of the plurality of temperature measurement means, based at least in part, on a determined operating state of the semiconductor package.

17. The semiconductor package of claim 15, wherein a first temperature measurement means of the plurality of temperature measurement means is adjacent a top portion of the enclosing means and a second temperature measurement means of the plurality of temperature measurement means is adjacent a side portion of the enclosing means.

18. The semiconductor package of claim 15, wherein at least one temperature measurement means of the plurality of temperature measurement means is attached to an inner surface of the enclosing means.

19. The semiconductor package of claim 15, wherein at least one temperature measurement means of the plurality of temperature measurement means is disposed in a molding compound between a top surface of the at least one semiconductor die and a top portion of the enclosing means.

20. The semiconductor package of claim 15, wherein the plurality of temperature measurement means are arranged on a single wafer within the enclosing means.
